(19) United States
(12) Patent Application Publication
(10) Pub. No.: US 2012/0002461 A1
(43) Pub. Date: Jan. 5, 2012

(54) NON-VOLATILE MEMORY WITH OVONIC THRESHOLD SWITCH AND RESISTIVE MEMORY ELEMENT

(76) Inventors: Elijah I. Karpov, Santa Clara, CA (US); Gianpaolo Paolo Spadini, Campbell, CA (US)

(21) Appl. No.: 12/830,086

(22) Filed: Jul. 2, 2010

(51) Int. Cl. G11C 11/00; H01L 21/02

(52) U.S. Cl. 365/158; 438/3; 257/E21.002; 365/148; 438/104

(57) ABSTRACT

The present disclosure relates to the fabrication of non-volatile memory devices. In at least one embodiment, the non-volatile memory of the present disclosure may include a resistive memory element with an ovonic threshold switch. The ovonic threshold switch may be connected in series with the resistive memory element and may act as an isolation device for the resistive memory element.

### BACKGROUND OF THE INVENTION

The present disclosure relates generally to the fabrication of microelectronic memory. The microelectronic memory may be non-volatile, wherein the memory can retain stored information even when not powered.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a schematic diagram illustrating a memory array in accordance with one embodiment of the present description;

FIG. 2 is a schematic diagram illustrating a memory stack in accordance with one embodiment of the present description;

FIGS. 3-8 illustrate side cross-sectional views of an embodiment of fabricating a memory cell of the present description;

FIG. 9 is a side cross-section view of an embodiment of stacked memory cells of the present description;

FIG. 10 is a flow diagram of a process of fabricating a memory cell of the present description; and

FIG. 11 is a schematic depiction of a system in accordance with one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description relate to the fabrication of non-volatile memory devices. In at least one embodiment, the non-volatile memory of the present disclosure may include a resistive memory element with an ovonic threshold switch. The ovonic threshold switch may be connected in series with the resistive memory element and may act as an isolation device for the resistive memory element.

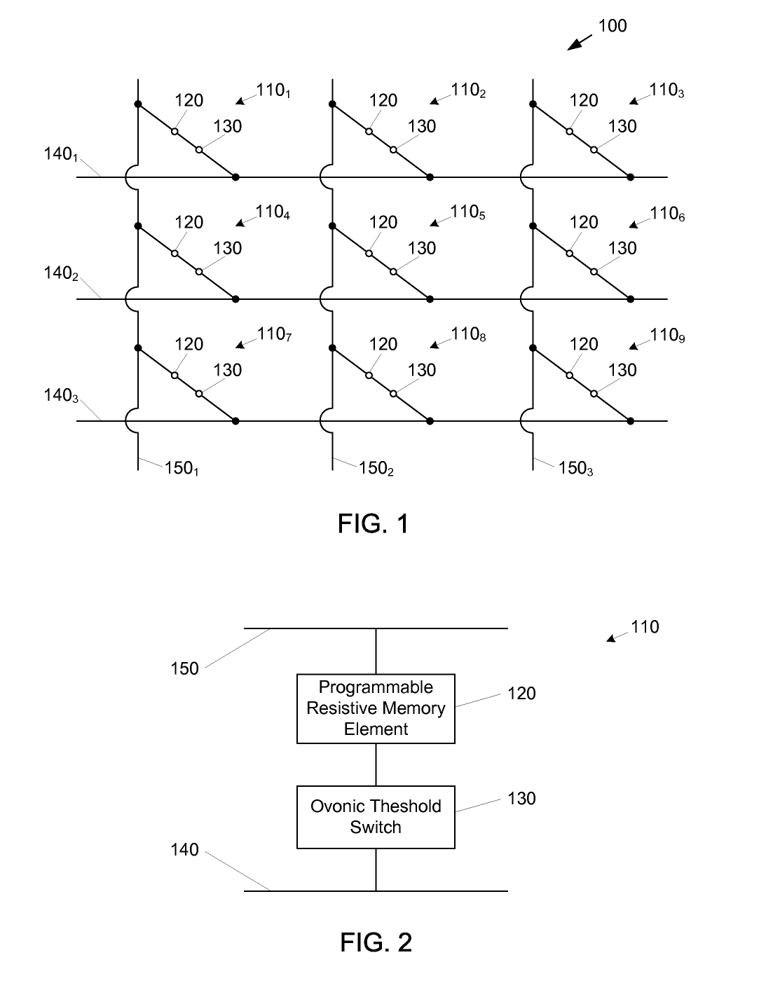

FIG. 1 shows a memory array 100 comprising, for illustration purposes, a 3×3 array of memory cells 110₁-110₉, and FIG. 2 shows a single memory cell 110 (analogous to any of memory cells 110₁-110₉ of FIG. 1). Each memory cell (110 and 110₁-110₉) may include a resistive memory element 120 and an ovonic threshold switch 130.

The memory array 100 may include column lines 150₁, 150₂, and 150₃ (shown as element 150 in FIG. 2) and row lines 140, 140₁, 140₂, and 140₃ (shown as element 140 in FIG. 2) to select a particular memory cell of the array during a write or read operation. The column lines 150, 150₁, 150₂, and 150₃ and the row lines 140, 140₁, 140₂, and 140₃ may also be referred to as “address lines” since these lines may be used to address memory cells 110, 110₁-110₉ during programming or reading. The column lines 150, 150₁, 150₂, and 150₃ may also be referred to as “bit lines”, and the row lines 140, 140₁, 140₂, and 140₃ may also be referred to as “word lines”. Further, it is understood that the 3×3 array of FIG. 1 is merely exemplary and may be any appropriate size (i.e, number of memory cells).

The resistive memory elements 120 may be connected to the column lines 150, 150₁, 150₂, and 150₃ and may be coupled to the row lines 140, 140₁, 140₂, and 140₃ through the ovonic threshold switch 130. Each ovonic threshold switch 130 may be connected in series to each resistive memory element 120 and may be used to access each resistive memory element 120 during programming or reading of each resistive memory element 120. When a particular memory cell (e.g., memory cell 110 of FIG. 2) is selected, voltage potentials may be applied to its associated column line (e.g., element 150 of FIG. 2) and row line (e.g., element 140 of FIG. 2) to apply a voltage potential across the memory cell. It is understood that each ovonic threshold switch 130 could positioned between each resistive memory element 120 and the column lines 150, 150₁, 150₂, and 150₃ with each resistive memory element 120 coupled to the row lines 140, 140₁, 140₂, and 140₃. It is also understood that more than one ovonic threshold switch 130 could be used within each memory cell 100, 100₁-100₉.

As will be understood to those skilled in the art, two terminal devices that act as programmable resistors cannot be correctly decoded if placed in an orthogonal arrangement of row lines 140 and column lines 150, as non-linear switching elements, such as transistors or a diode, must be put in series with the memory element. The connection of the ovonic threshold switch 130 as an isolation device in series with resistive memory element 120, as described in the present disclosure, allows the memory array 100 to be fabricated with orthogonal row lines 140 and column lines 150, which can result in lower fabrication costs.

The resistive memory element 120 may be made of a programmable metal oxide, which may be normally insulating, but can be changed to be conductive through a conductive path or multiple conductive paths that may be formed during the application of a sufficiently high voltage. The conductive paths may be formed by different mechanisms, including, but not limited to defects, metal migration, migration of ions species, and the like. Once conductive paths are formed, they may be “reset” (broken) resulting in a high resistance, or “set” (re-formed) resulting in a lower resistance by appropriately applied electrical pulses, which may be in the range suitable to application in integrated circuits, as will be understood to those skilled in the art. Data is stored by identifying the state of the resistance level in the programmable metal oxide. It is understood that the metal oxide material could be programmed and read at intermediate resistances which may increase data storage and reduce processing costs.

In one embodiment, the programming of the memory cell 110 may occur with electrical pulses applied between the row line 140 and the column line 150. Programming for a high resistance state to a low resistance state, and vice versa, can be implemented by the same or different voltages pulses with the same or different current limit. It is understood that a variety of methods known in the art can be used to read the state of the memory cell 110. In one embodiment, a voltage pulse may be applied until a predetermined current is detected. The voltage required will be high for a high resistive state or low for the low resistive state of the resistive memory element 120.

The ovonic threshold switch 130 can be made of a chalcogenide alloy that does not exhibit an amorphous to crystalline phase change and which undergoes rapid, electric field initiated change in electrical conductivity that persists only so long as a holding voltage is present. A chalcogenide material may be a material that includes at least one element from column VI of the periodic table or may be a material that includes one or more of the chalcogenide elements, e.g., any of the elements of tellurium, sulfur, or selenium.

The ovonic threshold switch 130 may operate as a switch that is either “off” or “on” depending on the amount of voltage potential applied across the memory cell, and more particularly whether the current through the select device exceeds its threshold current or voltage, which then triggers the device into the “on” state. The “off” state may be a substantially electrically nonconductive state and the “on” state may be a substantially conductive state, with less resistance than the “off” state. In the “on” state, the voltage across the select device is equal to its holding voltage V_{H} plus I×Rₒₙ, where Rₒₙ is the dynamic resistance from V_{H}. For example, the ovonic threshold switch 130 may have threshold voltage and, if a voltage potential less than the threshold voltage of the ovonic threshold switch 130 is applied across the ovonic threshold switch 130, then at least one ovonic threshold switch 130 may remain “off” or in a relatively high resistive state so that little or no electrical current passes through the memory cell and most of the voltage drop from selected row to selected column is across the select device. Alternatively, if a voltage potential greater than the threshold voltage of the ovonic threshold switch 130 is applied across the ovonic threshold switch 130, then the ovonic threshold switch 130 may turn “on”, i.e., operate in a relatively low resistive state so that electrical current passes through the memory cell. In other words, the ovonic threshold switch 130 may be in a substantially electrically nonconductive state if less than a predetermined voltage potential, e.g., the threshold voltage, is applied across the ovonic threshold switch 130. The ovonic threshold switch 130 may be in a substantially conductive state if a greater than the predetermined voltage potential is applied across the ovonic threshold switch 130. The ovonic threshold switch 130 may also be referred to as an access device, an isolation device, or a switch.

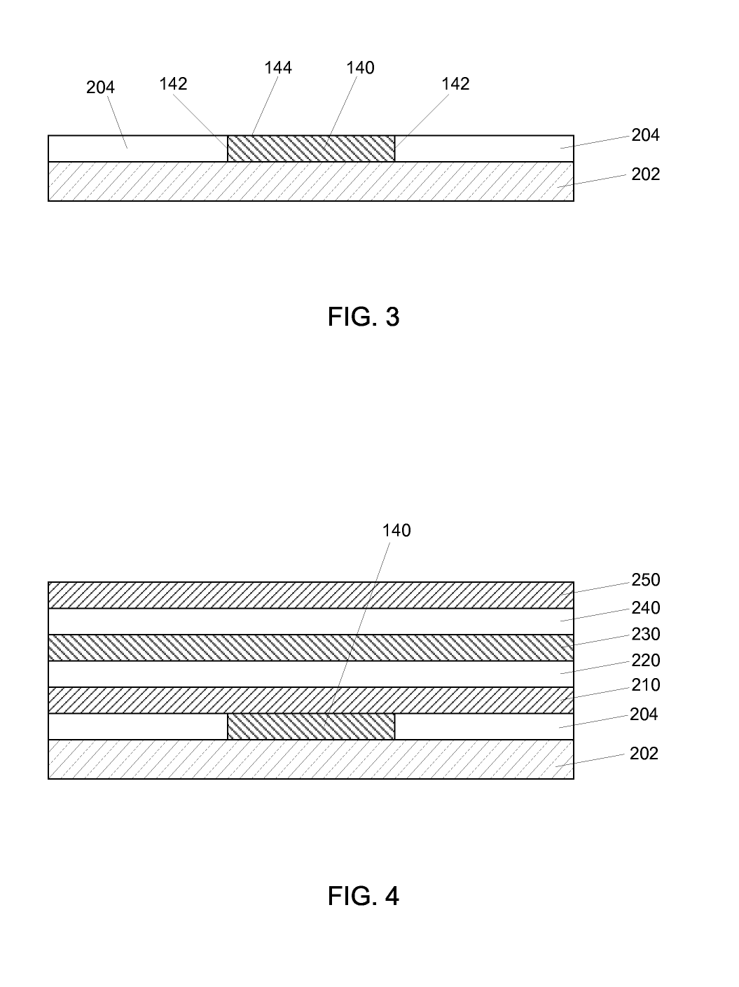

FIGS. 3-8 illustrate one embodiment of forming a memory cell of the present description. As shown in FIG. 3, a row line 140 may be formed on a microelectronic substrate 202 with a first dielectric material layer 204 abutting sides 142 of the row line 140. It is understood that the row line 140, as illustrated, would extend perpendicularly from the plane of FIG. 3 in three-dimensional space. The row line 140 and first dielectric material layer 204 may be form by another known technique including, but not limited to, lithography, deposition, plating, and chemical mechanical planarization. The microelectronic substrate 202 may be any appropriate material, including, but not limited to, silicon, silicon-on-insulator, gallium arsenide, indium phosphide, and the like. The first dielectric material layer 204 may be any appropriate material, including, but not limited to, silicon dioxide, silicon nitride, fluorinated silicon dioxide, carbon-doped silicon dioxide, silicon carbide, various polymeric dielectric materials, and the like. The row line 140 may be patterned from any appropriate electrically conductive materials, including, but not limited to copper, aluminum, silver, titanium, gold, alloys thereof, and the like.

As shown in FIG. 4, a lower electrode layer 210 may be formed over the first dielectric layer 204 and over an upper surface 144 of the row line 140. An ovonic threshold switch material 220 may be formed on the lower electrode layer 210. A middle electrode layer 230 may be formed on the ovonic switch material 220. A resistive memory material 240 may be formed on the middle electrode layer 230.

An upper electrode layer 250 may be formed on the resistive memory material 240. The lower electrode layer 210, the middle electrode layer 230, and the upper electrode layer 250 may be any appropriate electrically conductive materials, including, but not limited to copper, aluminum, silver, titanium, gold, alloys thereof, and the like. In one embodiment, the lower electrode layer 210, the middle electrode layer 230, and the upper electrode layer 250 may be metal nitride alloys, including, but not limited to, titanium nitride, titanium aluminum nitride, titanium silicon nitride, and tantalum nitride. It is understood that the select of the material used for the electrode will depend on its compatibility with a selected ovonic threshold switch material 220 and/or resistive memory material 240.

In one embodiment, the lower electrode layer 210, the middle electrode layer 230, and the upper electrode layer 250 may each have a thickness ranging from about 20 angstroms to about 2000 angstroms. In another embodiment, the lower electrode layer 210, the middle electrode layer 230, and the upper electrode layer 250 may have thicknesses ranging from about 1000 angstroms. In still another embodiment, the thickness of the lower electrode layer 210, the middle electrode layer 230, and the upper electrode layer 250 may each be about 300 angstroms thick.

As previously discussed, the ovonic threshold switch material 220 can be made of a chalcogenide alloy. In one embodiment, the ovonic threshold switch material 220 may comprise a composition of about 14% (atomic) silicon, about 39% (atomic) tellurium, about 37% (atomic) arsenic, about 9% (atomic) germanium, and about 1% (atomic) indium. In another embodiment, the ovonic threshold switch material 220 may comprise a composition a composition of about 14% (atomic) silicon, about 39% (atomic) tellurium, about 37% (atomic) arsenic, about 9% (atomic) germanium, and about 1% (atomic) phosphorus. In still another embodiment, the ovonic threshold switch material 220 may comprise a composition of about 50% (atomic) selenium, about 21% (atomic) tellurium, about 15% (atomic) germanium, about 10% (atomic) arsenic, about 2% (atomic) sulfur, and about 2% (atomic) antimony. In still yet another embodiment, the ovonic threshold switch material 220 may comprise a composition of about 34% (atomic) tellurium, about 28% (atomic) arsenic, about 11% (atomic) germanium, about 21% (atomic) sulfur, about 5% (atomic) silicon, and about 1% (atomic) selenium.

As previously discussed, the resistive memory material 240 can be made of a metal oxide. In one embodiment, the resistive memory material 240 may comprise copper oxide, nickel oxide, zinc oxide, hafnium oxide, cobalt oxide, zirconium oxide, titanium oxide, titanium-nickel oxide, magnesium oxide, aluminum oxide, tungsten oxide, and the like.

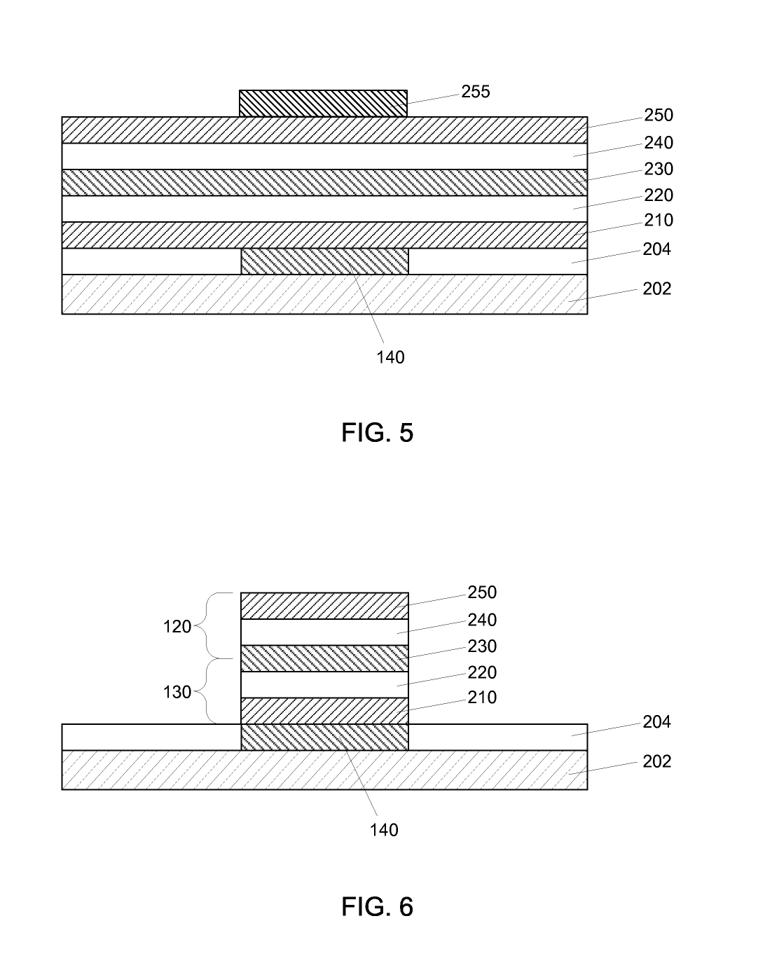

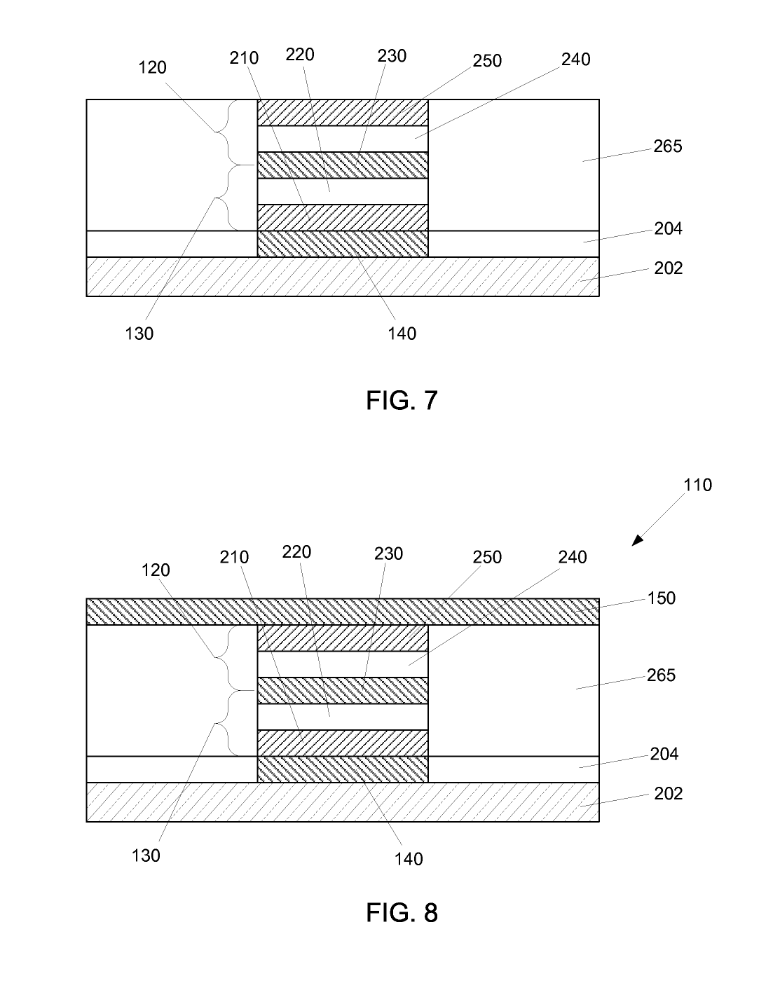

As shown in FIG. 5, a mask 255 may be formed on the upper electrode layer 250, such as by known lithographic techniques. The upper electrode layer 250, the resistive memory material 240, the middle electrode layer 230, the ovonic threshold switch material 220, and lower electrode layer 210 may be etched to form a memory stack 260 comprising the resistive memory element 120 and the ovonic threshold switch 130, as shown in FIG. 6. As shown in FIG. 7, a second dielectric material layer 265 may be formed to abut the memory stack 260. The second dielectric material layer 265 may be any appropriate material, including, but not limited to, silicon dioxide, silicon nitride, fluorinated silicon dioxide, carbon-doped silicon dioxide, silicon carbide, various polymeric dielectric materials, and the like. As shown in FIG. 8, a column line 150 may be formed on the second dielectric material layer 265 and contact the upper electrode layer 250, thereby forming the memory cell 110.

As will be understood to those skilled in the art, the elements illustrated in FIGS. 3-8 can be fabricated by any known fabrication techniques. It is also understood that although the memory stack 260 is shown to be formed with a single etch, it may be formed with multiple etch steps. Furthermore, the memory stack 260 could be formed by etching each layer or combination of layers as they are formed.

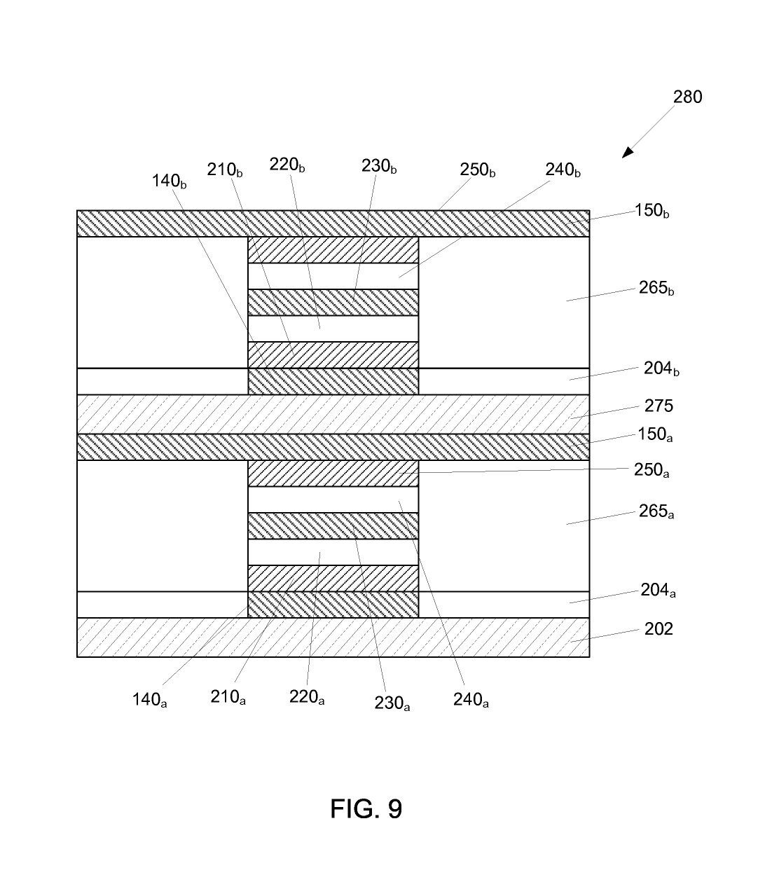

As will be understood to those skilled in the art, the elements and fabrication techniques describe may be performed at relatively low temperatures, which will allow for the stacking of the memory arrays (see FIG. 1) in a vertical fashion, thereby reducing the size of memory devices. FIG. 9 illustrates a stacked memory device 270 comprising a lower memory array 100ₐ and an upper memory array 100_{b} separated by a stack dielectric layer 275. Elements which are common with the elements in FIGS. 1-8 are similarly numbered, wherein the elements for the lower memory 100ₐ are denoted with an “a” subscript and the elements of the upper memory array 100_{b} are denoted with a “b” subscript.

Although the present description is directed to resistive memory elements 120 fabricated from metal oxides, it is understood that the resistive memory elements 120 can be magnetoresistive memory elements. With a magnetoresistive memory element, data is stored by changing the magnetization of a layer in a stack and that, in turn, changes its resistance. The substitution of a magnetoresistive memory element for the illustrated metal oxide resistive memory element, and associated structures, will be evident to those skilled in the art.

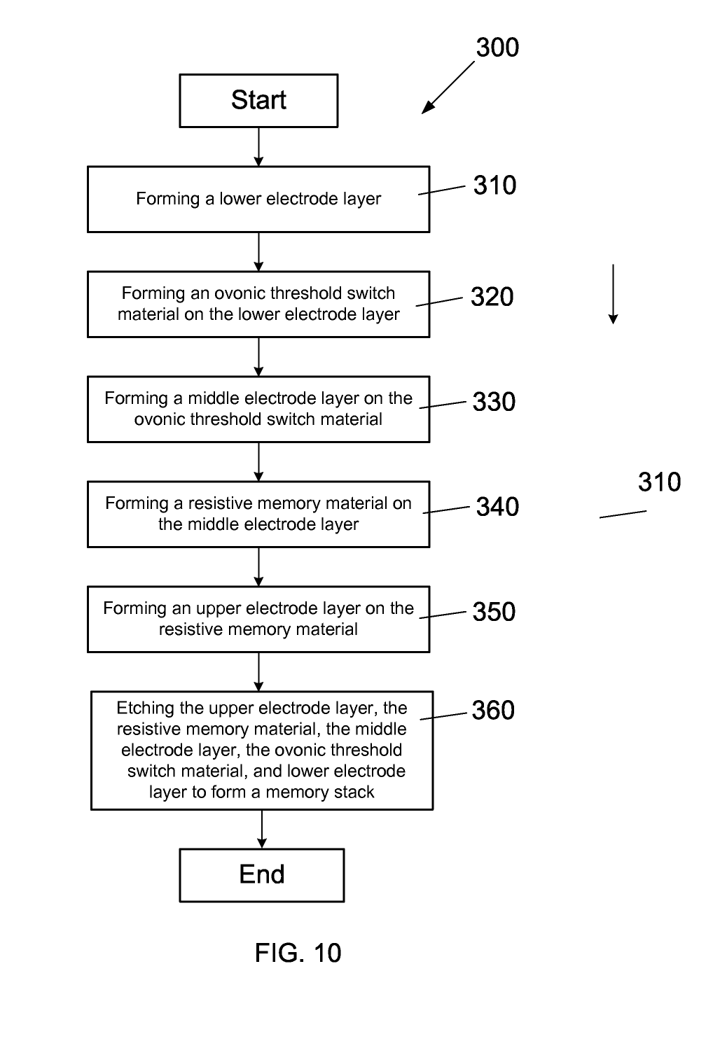

An embodiment of a process of forming a non-volatile memory of the present description is illustrated in the flow diagram 300 of FIG. 10. As defined in block 310, a lower electrode layer may be formed on a microelectronic substrate and an ovonic threshold switch material on the lower electrode layer, as defined in block 320. A middle electrode layer may be formed on the ovonic threshold switch, as shown in block 330, and a resistive memory material may be formed on the middle electrode layer, as shown in block 340. An upper electrode layer may be formed on the resistive memory material, as shown in block 350. The upper electrode layer, the resistive memory material, the middle electrode layer, the ovonic threshold switch material, and lower electrode layer may be etched to form a memory stack, as shown in FIG. 360.

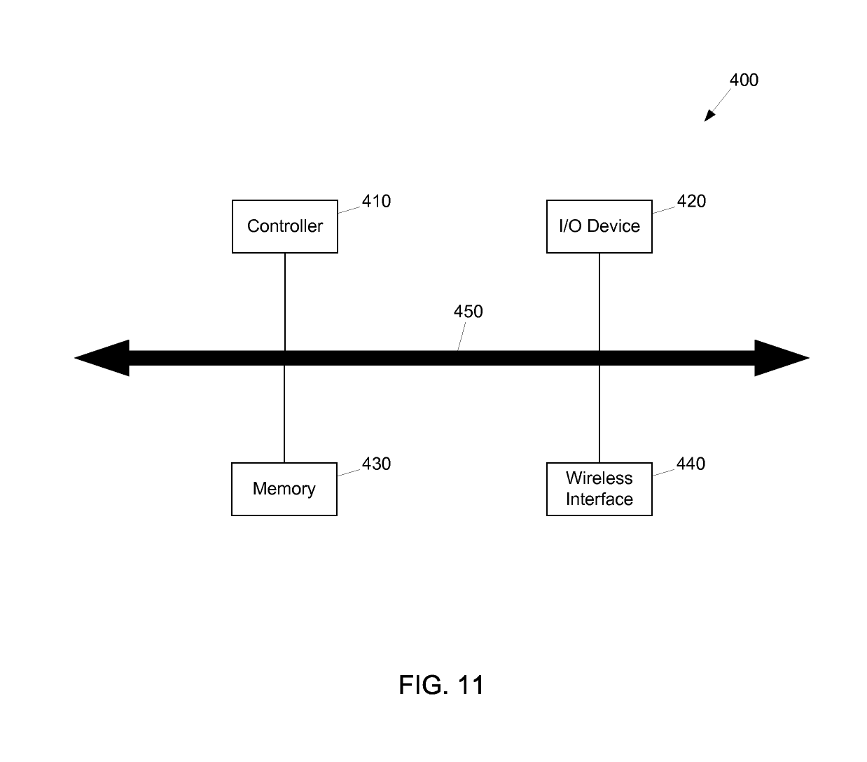

FIG. 11 illustrates an example of a microelectronic system 400 utilizing the subject matter of the present description. The microelectronic system 400 may be any electronic device, including but not limited to portable devices, such as a portable computer, a mobile telephone, a digital camera, a digital music player, a web tablet, a personal digital assistant, a pager, an instant messaging device, or other devices, The microelectronic system 400 may be adapted to transmit and/or receive information wirelessly, such as through a wireless local area network (WLAN) system, a wireless personal area network (WPAN) system, and/or a cellular network.

The microelectronic system 400 may include a controller 410, an input/output (I/O) device 420 (e.g. a keypad, display, and the like), a memory 430, and a wireless interface 440 coupled to each other via a bus 450. It is understood that the scope of the present invention is not limited to embodiments having any or all of these components.

The controller 410 may comprise, for example, one or more microprocessors, digital signal processors, application specific integrated circuits, microcontrollers, or the like. The memory 430 may be used to store messages transmitted to or by system 400. The memory 430 may also optionally be used to store instructions that are executed by controller 410 during the operation of system 400, and may be used to store user data. The memory 430 may be the provided by one or more different types of memory. For example, the memory 430 may comprise any type of random access memory, a volatile memory, a non-volatile memory such as a flash memory and/or a memory such as memory 100 discussed herein.

The I/O device 420 may be used by a user to generate a message. The system 400 may use the wireless interface 440 to transmit and receive messages to and from a wireless communication network with a radio frequency (RF) signal. Examples of the wireless interface 440 may include an antenna or a wireless transceiver, although the scope of the present invention is not limited in this respect.

The detailed description has described various embodiments of the devices and/or processes through the use of illustrations, block diagrams, flowcharts, and/or examples. Insofar as such illustrations, block diagrams, flowcharts, and/or examples contain one or more functions and/or operations, it will be understood by those skilled in the art that each function and/or operation within each illustration, block diagram, flowchart, and/or example can be implemented, individually and/or collectively, by a wide range of hardware, software, firmware, or virtually any combination thereof.

The described subject matter sometimes illustrates different components contained within, or connected with, different other components. It is understood that such illustrations are merely exemplary, and that many alternate structures can be implemented to achieve the same functionality. In a conceptual sense, any arrangement of components to achieve the same functionality is effectively “associated” such that the desired functionality is achieved. Thus, any two components herein combined to achieve a particular functionality can be seen as “associated with” each other such that the desired functionality is achieved, irrespective of structures or intermediate components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

It will be understood by those skilled in the art that terms used herein, and especially in the appended claims are generally intended as “open” terms. In general, the terms “including” or “includes” should be interpreted as “including but not limited to” or “includes but is not limited to”, respectively. Additionally, the term “having” should be interpreted as “having at least”.

The use of plural and/or singular terms within the detailed description can be translated from the plural to the singular and/or from the singular to the plural as is appropriate to the context and/or the application.

It will be further understood by those skilled in the art that if an indication of the number of elements is used in a claim, the intent for the claim to be so limited will be explicitly recited in the claim, and in the absence of such recitation no such intent is present. Additionally, if a specific number of an introduced claim recitation is explicitly recited, those skilled in the art will recognize that such recitation should typically be interpreted to mean “at least” the recited number.

The use of the terms “an embodiment,” “one embodiment,” “some embodiments,” “another embodiment,” or “other embodiments” in the specification may mean that a particular feature, structure, or characteristic described in connection with one or more embodiments may be included in at least some embodiments, but not necessarily in all embodiments. The various uses of the terms “an embodiment,” “one embodiment,” “another embodiment,” or “other embodiments” in the detailed description are not necessarily all referring to the same embodiments.

While certain exemplary techniques have been described and shown herein using various methods and systems, it should be understood by those skilled in the art that various other modifications may be made, and equivalents may be substituted, without departing from claimed subject matter or spirit thereof. Additionally, many modifications may be made to adapt a particular situation to the teachings of claimed subject matter without departing from the central concept described herein. Therefore, it is intended that claimed subject matter not be limited to the particular examples disclosed, but that such claimed subject matter also may include all implementations falling within the scope of the appended claims, and equivalents thereof.

What is claimed is:

1. A non-volatile memory, comprising:
a resistive memory element; and
an ovonic threshold switch connected in series to the resistive memory element.

2. The non-volatile memory of claim 1, wherein the resistive memory element comprises a metal oxide material.

3. The non-volatile memory of claim 1, wherein the resistive memory element comprises a magnetoresistive memory element.

4. The non-volatile memory of claim 1, wherein the ovonic threshold switch comprises a chalcogenide material.

5. The non-volatile memory of claim 1, further including a row line connected to one of the resistive memory element and the ovonic threshold switch, and a column line connected to the other of the resistive memory element and the ovonic threshold switch.

6. The non-volatile memory of claim 1, further comprising:
a row line;
a column line;
a lower electrode connected to the ovonic threshold switch;
the ovonic threshold switch connected to a middle electrode;
the middle electrode connected to the resistive memory element;
the resistive memory element to an upper electrode;
the lower electrode connected to one of the row line and the column line; and
the upper electrode connected to other of the row line and the column line.

7. The non-volatile memory of claim 7, wherein the row line and the column line are in a substantially orthogonal relationship to one another.

8. A method of fabricating a non-volatile memory, comprising:
forming a lower electrode layer;
forming an ovonic threshold switch material on the lower electrode layer;
forming a middle electrode layer on the ovonic threshold switch material;
forming a resistive memory material on the middle electrode layer;
forming an upper electrode layer on the resistive memory material; and
etching the upper electrode layer, the resistive memory material, the middle electrode layer, the ovonic threshold switch material, and lower electrode layer to form a memory stack.

9. The method of claim 8, wherein forming the resistive memory material comprises forming a resistive memory material including a metal oxide material on the middle electrode layer.

10. The method of claim 8, wherein forming the resistive memory material comprises forming a resistive memory material including a magnetoresistive memory material on the middle electrode layer.

11. The method of claim 8, wherein forming the ovonic threshold switch comprises forming an ovonic threshold switch comprising a chalcogenide material on the lower electrode layer.

12. The method of claim 8, further comprising forming a row line connected to one of the lower electrode material and the upper electrode material, and forming a column line connected to the other of the lower electrode material and the upper electrode material.

13. The method of claim 12, wherein forming the row line and forming the column line comprises forming the row line and the column line in a substantially orthogonal relationship to one another.

14. A system, comprising:
a controller; and
a non-volatile memory comprising a resistive memory element and a ovonic threshold switch connected in series to the resistive memory element.

15. The system of claim 14, further including a wireless interface coupled to the controller.

16. The system of claim 14, wherein the resistive memory element comprises a metal oxide material.

17. The system of claim 14, wherein the resistive memory element comprises magnetoresistive memory element.

18. The system of claim 14, wherein the ovonic threshold switch comprises a chalcogenide material.

19. The system of claim 14, further including a row line connected to one of the resistive memory element and the ovonic threshold switch, and a column line connected to the other of the resistive memory element and the ovonic threshold switch.

20. The system of claim 14, further comprising:
a row line;
a column line;
a lower electrode connected to the ovonic threshold switch;
the ovonic threshold switch connected to a middle electrode;
the middle electrode connected to the resistive memory element;
the resistive memory element to an upper electrode;
the lower electrode connected to one of the row line and the column line; and
the upper electrode connected to other of the row line and the column line.
